(19) United States
(12) Patent Application Publication
(10) Pub. No.: US 2018/0182993 A1
(43) Pub. Date: Jun. 28, 2018

(54) FLEXIBLE DISPLAY PANEL AND FLEXIBLE DISPLAY DEVICE

(71) Applicant: Wuhan China Star Optoelectronics Technology Co., Ltd., Wuhan, Hubei (CN)

(72) Inventor: Yuejun TANG, Shenzhen, Guangdong (CN)

(73) Assignee: Wuhan China Star Optoelectronics Technology Co., Ltd., Wuhan, Hubei (CN)

(21) Appl. No.: 15/324,688

(22) PCT Filed: Jan. 5, 2017
(86) PCT No.: PCT/CN2017/070194

§ 371 Date: Jan. 7, 2017

(30) Foreign Application Priority Data
Nov. 11, 2016 (CN) 2016110056322

(51) Int. Cl. H01L 51/52; H01L 27/32

(52) U.S. Cl. CPC H01L 51/525; H01L 51/5253; H01L 51/56; H01L 2251/5338; H01L 27/3262

(57) ABSTRACT

A flexible display panel and a flexible display device are disclosed. Through disposing multiple additional supporting structures at at least one location of an upper location, a lower location and an internal location of the substrate and the packaging layer, a flat display surface for displaying a high quality picture, easily to be mounted on the wall and easily maintaining a status after bending are provided. Besides, a good bendable performance can be achieved such that the internal devices are not easily to be bent when bending.

### BACKGROUND OF THE INVENTION

### 1. Field of the Invention

The present invention relates to a display technology field, and more particularly to a flexible display panel and flexible display device having the flexible display panel.

### 2. Description of Related Art

A flexible display panel has a flexible feature such that when using the flexible display panel, more inconvenience is generated. For example, when the flexible display panel is placed at an uneven surface, a flat display surface for displaying a high quality picture cannot be provided. Besides, the flexible display panel is not easily to be mounted on the wall and a status after bending is not easily to be maintained. Besides, the bendable performance is poor and the internal devices are easily to be damaged when bending, especially a semiconductor layer and a stacked structure formed by multiple metal layers of the thin-film transistor (TFT). Besides, along with the increasing of the number of the bending, the damage is more and more serious. Accordingly, to improve the bendable performance of the flexible display panel becomes more and more important.

### SUMMARY OF THE INVENTION

Accordingly, the present invention provides a flexible display panel and a flexible display device. A flat display surface for displaying a high quality picture, easily to be mounted on the wall and easily maintaining a status after bending are provided. Besides, a good bendable performance can be achieved such that the internal devices are not easily to be bent when bending.

The flexible display panel of one embodiment of the present invention comprises: a substrate; a light-emitting layer; a packaging layer; and a supporting structure made of a rigid material; wherein, the light-emitting layer is disposed between the substrate and the packaging layer, and is provided with a thin-film transistor; the supporting structure is disposed at least one location of an upper location, a lower location and an internal location of the substrate and the packaging layer; the supporting structure is formed correspondingly above and/or below the thin-film transistor through etching or adhering by transfer printing; an elastic modulus of the supporting structure is greater than an elastic modulus of the flexible display panel; and a bending strength of the supporting structure is greater than or equal to 400 MPa.

Wherein, the supporting structure includes multiple stripe-shaped rigid bars, a width of each rigid bar is greater than or equal to a width of a semiconductor layer of the thin-film transistor.

The flexible display panel of one embodiment of the present invention comprises: a substrate; a packaging layer; and a supporting structure; wherein, the supporting structure is disposed at least one location of an upper location, a lower location and an internal location of the substrate and the packaging layer.

Wherein, the flexible display panel further includes a light-emitting layer disposed between the substrate and the packaging layer, the light-emitting layer is provided with a thin-film transistor, the supporting structure is formed above and/or below the thin-film transistor, and disposed corresponding to the thin-film transistor.

Wherein, the supporting structure includes multiple stripe-shaped rigid bars, a width of each rigid bar is greater than or equal to a width of a semiconductor layer of the thin-film transistor.

Wherein, the supporting structure includes multiple rigid blocks, an area of each block is less than an area of a sub-pixel of the flexible display panel.

Wherein, an elastic modulus of the supporting structure is greater than an elastic modulus of the flexible display panel; and a bending strength of the supporting structure is greater than or equal to 400 MPa.

Wherein, the flexible display panel includes a display region located at a middle portion and a non-display region located at periphery of the display region, the supporting structure includes a first supporting bar corresponding to the display region and/or a second supporting bar corresponding to the non-display region.

Wherein, a width of the second supporting bar is greater than a width of the first supporting bar.

Wherein, at least one of the first supporting bar and the second supporting bar is magnetic.

Wherein, a length direction of each supporting structure is perpendicular to a bendable direction of the flexible display panel.

The flexible display device provided by the present embodiment comprises: a substrate; a packaging layer; and a supporting structure; wherein, the supporting structure is disposed at least one location of an upper location, a lower location and an internal location of the substrate and the packaging layer.

Wherein, the flexible display panel further includes a light-emitting layer disposed between the substrate and the packaging layer, the light-emitting layer is provided with a thin-film transistor, the supporting structure is formed above and/or below the thin-film transistor, and disposed corresponding to the thin-film transistor.

Wherein, the supporting structure includes multiple stripe-shaped rigid bars, a width of each rigid bar is greater than or equal to a width of a semiconductor layer of the thin-film transistor.

Wherein, the supporting structure includes multiple rigid blocks, an area of each block is less than an area of a sub-pixel of the flexible display panel.

Wherein, an elastic modulus of the supporting structure is greater than an elastic modulus of the flexible display panel; and a bending strength of the supporting structure is greater than or equal to 400 MPa.

Wherein, the flexible display panel includes a display region located at a middle portion and a non-display region located at periphery of the display region, the supporting structure includes a first supporting bar corresponding to the display region and/or a second supporting bar corresponding to the non-display region.

Wherein, a width of the second supporting bar is greater than a width of the first supporting bar.

Wherein, at least one of the first supporting bar and the second supporting bar is magnetic.

Wherein, a length direction of each supporting structure is perpendicular to a bendable direction of the flexible display panel.

Beneficial effect: in the embodiment of the present invention, through disposing multiple additional supporting structures at at least one location of an upper location, a lower location and an internal location of the substrate and the packaging layer, a flat display surface for displaying a high quality picture, easily to be mounted on the wall and easily maintaining a status after bending are provided. Besides, a good bendable performance can be achieved such that the internal devices are not easily to be bent when bending.

### BRIEF DESCRIPTION OF THE DRAWINGS

FIG. 1 is a structural cross-sectional view of a flexible display panel according to a first embodiment of the present invention;

FIG. 2 is a partial structural schematic diagram of the flexible display panel shown in FIG. 1;

FIG. 3 is a structural cross-sectional view of a flexible display panel according to a second embodiment of the present invention;

FIG. 4 is a partial structural schematic diagram of the flexible display panel shown in FIG. 3;

FIG. 5 is a structural cross-sectional view of a flexible display panel according to a third embodiment of the present invention;

FIG. 6 is a partial structural schematic diagram of the flexible display panel shown in FIG. 5;

FIG. 7 is a structural cross-sectional view of a flexible display panel according to a fourth embodiment of the present invention;

FIG. 8 is a partial structural schematic diagram of the flexible display panel shown in FIG. 7;

FIG. 9 is a structural cross-sectional view of a flexible display panel according to a fifth embodiment of the present invention;

FIG. 10 is a top view of rigid bars according to an embodiment of the present invention;

FIG. 11 is a top view of rigid bars according to another embodiment of the present invention;

FIG. 12 is a top view of rigid blocks according to an embodiment of the present invention;

FIG. 13 is a structural schematic diagram when the flexible display panel is bent according to a sixth embodiment of the present invention;

FIG. 14 is a structural top view of supporting bars according to a first embodiment of the present invention;

FIG. 15 is a structural top view of supporting bars according to a second embodiment of the present invention;

FIG. 16 is a structural top view of supporting bars according to a third embodiment of the present invention;

FIG. 17 is a structural top view of supporting bars according to a fourth embodiment of the present invention;

FIG. 18 is a schematic diagram of the flexible display panel shown in FIG. 13 being placed on an uneven surface;

FIG. 19 is a front view of the flexible display panel shown in FIG. 13 being mounted on the wall; and

FIG. 20 is a structural cross-sectional view of a flexible display device according to an embodiment of the present invention.

### DETAILED DESCRIPTION OF THE PREFERRED EMBODIMENT

The following will combine the figures in the embodiments of the present invention to describe the exemplary embodiments provided by the present invention clearly and completely. In the absence of conflict, the technology features of the following embodiments can be combined with each other. Besides, the directional terms adopted by the specification of the present invention such as “upper” or “lower” are all for illustrate each embodiment better, not for limiting the scope of the present invention.

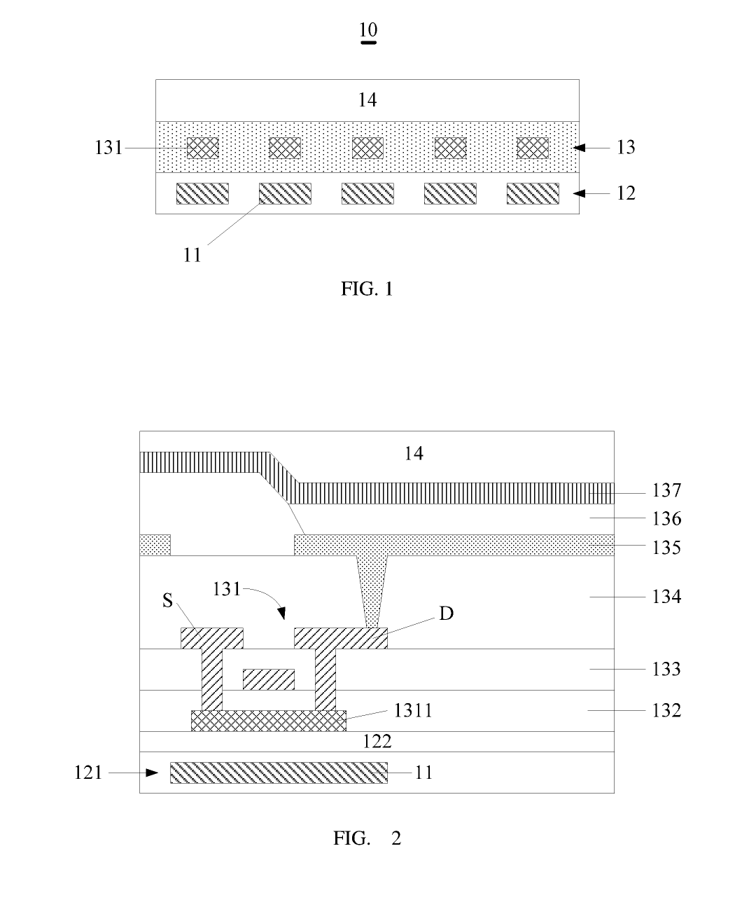

With reference to FIG. 1, and FIG. 1 is a flexible display panel according to an embodiment of the present invention. The term “flexible” means that the display panel can be bent, that is, can be folded. The display panel 10 includes a supporting structure 11, and the supporting structure is disposed corresponding to devices (for example, including but not limited to a semiconductor layer of a thin-film transistor and a stacked structure formed by multiple metal layers) inside the display panel in order to protect that the devices corresponding to the supporting structure 11 will not be bent or only be slightly bent so as to protect the devices from damaging by bending. Wherein, the term “disposed correspondingly” can be understood as: along a slight direction which is perpendicular to the display panel 10, at least a portion of a projection of the devices inside the display panel 10 can be located at a region where the supporting structure 11 is located. In other words, the devices and the supporting structure 11 are overlapped partially.

When the display panel 10 is bent, the devices corresponding to the supporting structure 11 is bent together with the supporting structure as an entirety so that the devices is not easily to be broken by bending and the display panel 10 has a good bendable performance.

Accordingly, the supporting structure 11 is preferably made by a rigid material. That is, each supporting structure 11 can be regarded as a rigid layer. The rigid material can be metal or inorganic material, etc. such as zirconium oxide, cobalt-chromium alloy or tungsten. The manufacturing process for the supporting structure 11 can be selected according to the rigid material adopted. For example, when the rigid material is metal, a mask can be adopted to block a portion without the rigid material and reveal a portion with the rigid material to manufacture the supporting structure 11. In another example, manufacturing a rigid surface having an entire surface in advance, then, using an etching method remove the useless rigid layer in order to obtain a supporting structure 11 having a predetermined structure. In another example, when the rigid material is an inorganic material, a patterned rigid layer can be manufactured in advance, then, through a transfer printing to adhere the patterned rigid layer to the corresponding structure of the display panel 10 in order to obtain the supporting structure 11 having a predetermined structure.

An elastic modulus can measure the degree of difficulty of a rigid material for generating an elastic deformation. When the value of the elastic modulus is greater, a larger stress is required to make the rigid material to generate an elastic deformation, that is, the stiffness is greater. In other words, under a certain stress, the elastic deformation of the supporting structure 11 is less. A bending strength is a maximum stress of a material when the material is cracked or reaches a specified deflection under a bending load. In the present embodiment, when the rigid material selected has a larger elastic modulus, the requirement for the stiffness of the supporting structure 11 can be meet. However, at this time, the bending strength of the supporting structure 11 should also be considered. If the bending strength is too small, in the bending process of the display panel, the supporting structure 11 is easily to be broken so that the purpose of no damage when bending to protect the device cannot be reached. Accordingly, preferably, in the present embodiment, an elastic modulus of the supporting structure 11 is greater than an elastic modulus a layer structure of the flexible display panel 10 overlapped with the supporting structure 11, and the bending strength of the supporting structure 11 is greater than or equal to 400 MPa.

With still reference to FIG. 1, in the present embodiment, the display panel 10 is simplified as a three-layered structure of a substrate 12, a light-emitting layer 13 and a packaging layer 14. The three-layered structure can include every part required by the display panel 10. For example, for a display panel 10 having an OLED (Organic Light-Emitting Diode) as shown in FIG. 2, the substrate 12 can include a base layer 121 and a buffering layer 122, light emitting devices in the light-emitting layer 13 can include a thin-film transistor 131, a gate insulation layer (GI layer) 132, an interlayer dielectric isolation layer (ILD) 133, a planarization layer 134, an anode 135, a light-emitting material layer 136 and a cathode 137. The packaging layer 14 is used for blocking water vapor and oxygen from entering.

Of course, for other types of the display panels 10, parts and manufacturing materials of the three-layered structure are different. For example, the manufacturing materials of the substrate 12 can be glass, metal, plastic or other complete flexible material, including but not limited to organic material of PI (Polyimide), etc., or stacked multiple layered structure formed by organic material of PI and inorganic material of SiO₂; the thin-film transistor of the light-emitting layer 13 can be manufactured by an amorphous silicon process, or a low temperature monocrystalline silicon process. The thin-film transistor can be a bottom-gate structure or a top-gate structure. The light-emitting material can be various suitable organic material or inorganic material. The packaging layer 14 can be a thin-film package, a cover package or a combination structure of the thin-film package and the cover package.

In the present embodiment, the multiple supporting structures 11 are disposed corresponding to the devices of the display panel 10. The specific locations can be arranged according to the devices includes in the display panel 10. Specifically, the multiple supporting structures 11 can be disposed at at least one location of an upper location, a lower location and an internal location of the substrate 12 and the packaging layer 14.

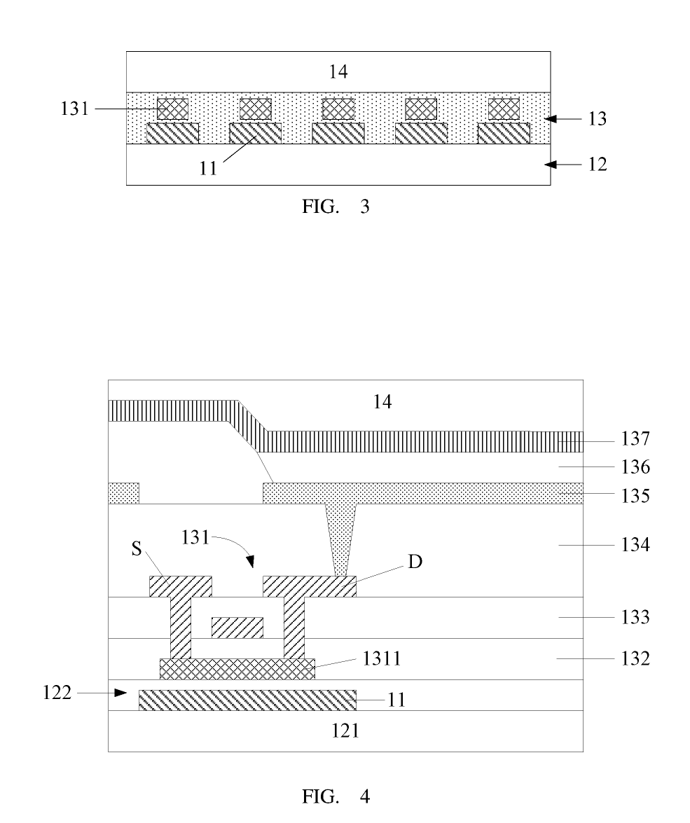

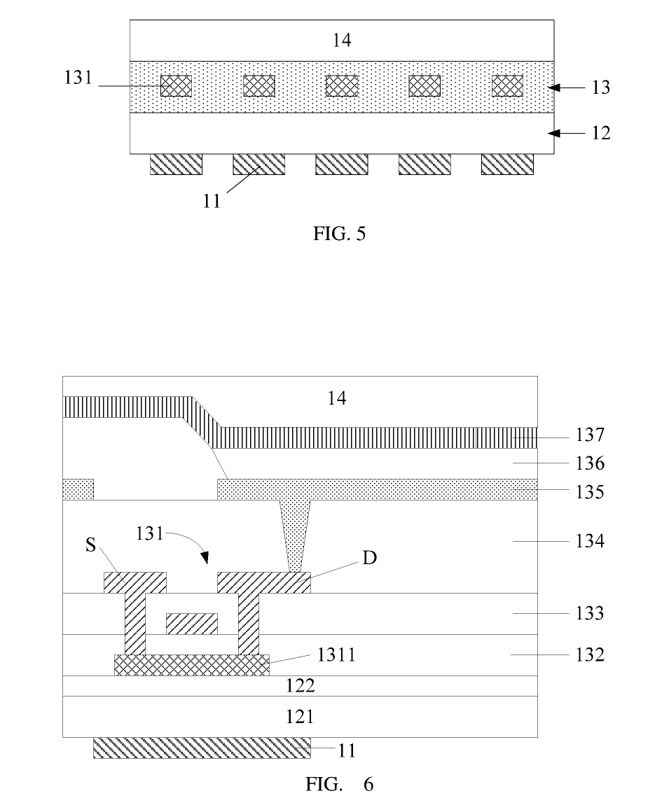

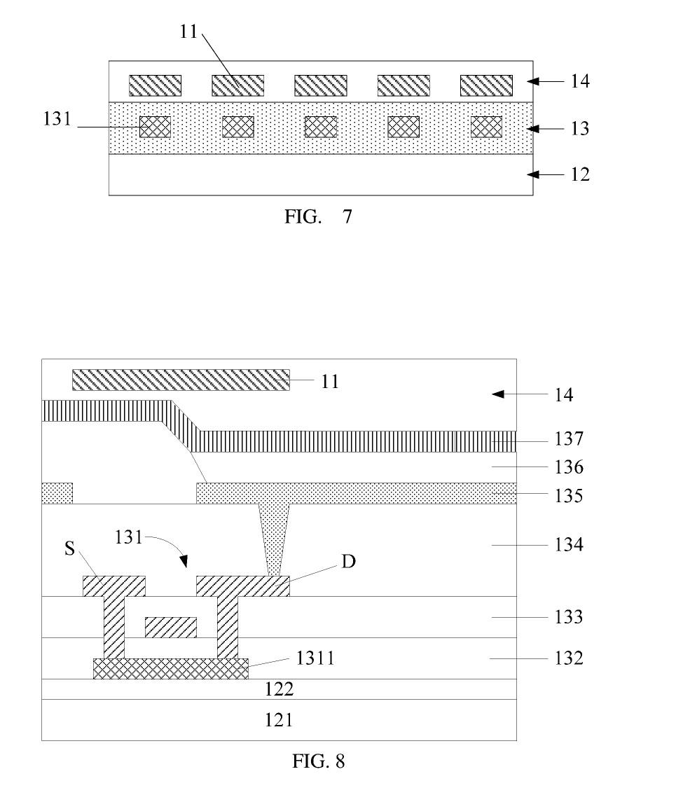

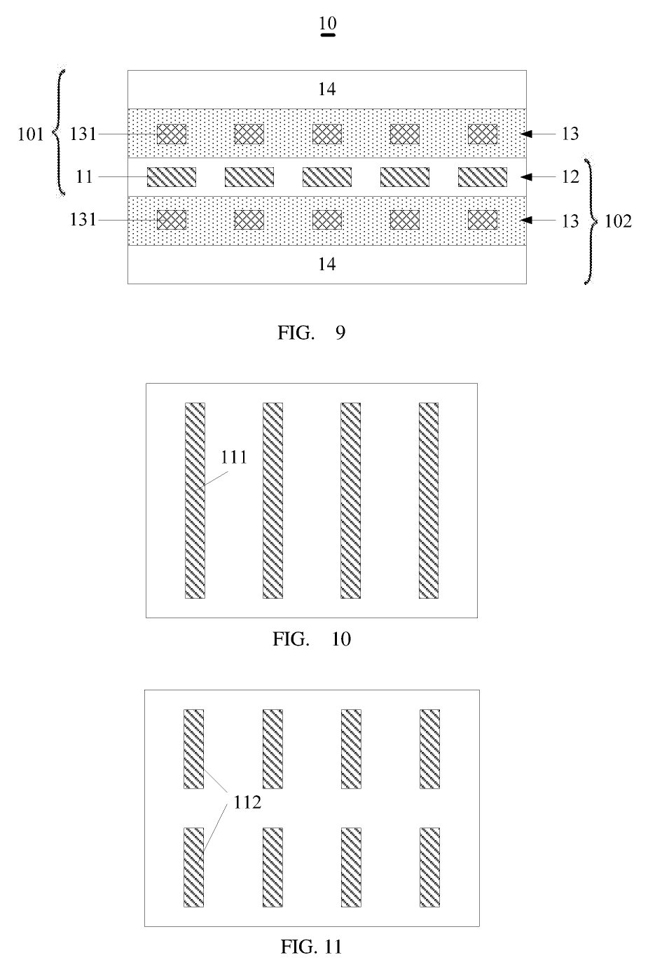

For example, for the OLED display panel 10: as shown in FIG. 1 and FIG. 2, the supporting structure 11 is disposed inside the substrate 12 and below the thin-film transistor 131; as shown in FIG. 3 and FIG. 4, the supporting structure 11 is disposed above the substrate 12 and below the thin-film transistor 131; as shown in FIG. 5 and FIG. 6, the supporting structure 12 is disposed on a lower surface of the substrate 12, and located below the thin-film transistor 131; as shown in FIG. 7 and FIG. 8, the supporting structure 11 is disposed inside the packaging layer 14, and located above the thin-film transistor 131; as shown in FIG. 9, for a double-side display panel 10 commonly using one substrate 12, that is, a first display panel 101 and a second display panel 102 commonly use one substrate 12, the supporting structure 12 is disposed inside the substrate 12, located above a thin-film transistor 131 of the first display panel 101, and located below the thin-film transistor 131 of the second display panel 102. That is, only one layer of the supporting structure 11 is required to protect the devices of the first display panel 101 and the second display panel 102 corresponding to the supporting structure 11.

It should be noted that in the embodiments shown in FIG. 1 to FIG. 9, the supporting structures 11 and the thin-film transistors 131 disposed correspondingly one by one is only for an example. In another embodiment, the supporting structures 11 and the thin-film transistors 131 may not be corresponded one by one. That is, the number of the supporting structures and the number of the thin-film transistors 131 do not have necessary relationship. The only requirement is that the supporting structure 11 and the device of the display panel are disposed correspondingly. When the display panel 10 is bent, the supporting structure 11 can protect the device corresponding to the supporting structure 11 (such as semiconductor layer 1311 of the thin-film transistor 131 shown in the figure) from being bent or only being bent slightly in order to protect the devices from bending and damaging.

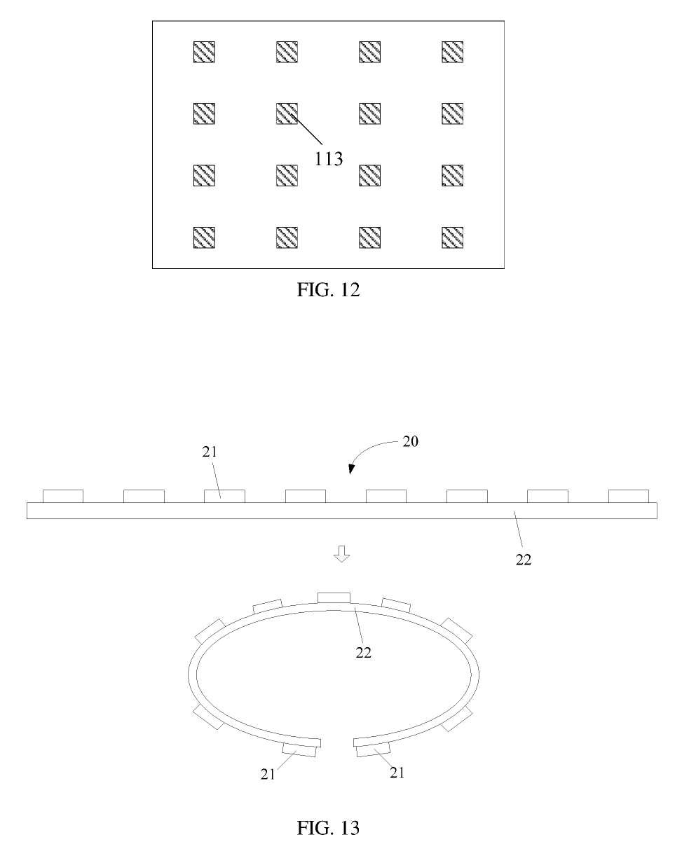

In the present embodiment, the supporting structure can be stripe-shaped or block-shaped. For example, as shown in FIG. 10, the supporting structure 11 includes multiple rigid bars 111. Each rigid bar 111 is in parallel with an edge of the display panel 10. As shown in FIG. 11, the supporting structures 11 includes multiple intermittent rigid bars 112, which is equal to separate each rigid bar 111 shown in FIG. 10 into multiple separated portions. Wherein, an intermittent distance between two rigid bars 112 is less than a size of a sub-pixel along a direction of the rigid bar 111. As shown in FIG. 12, the supporting structure 11 includes multiple rigid blocks 113 corresponding to devices (such as thin-film transistors 131) of the display panel 10.

Besides, when the supporting structure 11 is stripe-shaped, preferably, a width of each rigid bar 111 (or rigid bar 112) of the supporting structure 11 of the present embodiment is greater than or equal to a width of the semiconductor layer 1311 of the thin-film transistor 131. When the supporting structure 11 is block-shaped, preferably, an area of each rigid block 113 of the supporting structure 11 is less than an area of a sub-pixel of the display panel 10. Furthermore, preferably, in the present embodiment, a horizontal distance between an outer edge of the supporting structure 11 and a source electrode S or a drain electrode D of the thin-film transistor 131 is less than 10 um.

When the supporting structure 11 is located inside the substrate 12 and/or the packaging layer 14, preferably, in the embodiment of the present invention, the substrate 12 and/or the packaging layer 14 is a thin-film structure having multiple layers. For example, an alternate and stacked structure with multiple layers formed by flexible organic layer such as polyimide (PI) and inorganic layers such as SiOx and SiNx. On this basis, in the embodiment of the present invention, a side of the substrate 12 and/or the packaging layer 14 adjacent to the light-emitting material and closed to a surface of the supporting structure 11 is covered with one layer or multiple layers of inorganic layers in order to block impurities in the supporting structure 11 from entering into the light-emitting device of the light-emitting layer 13.

When the supporting structure 11 is located at an inner surface of the substrate 12 or the packaging layer 14, in the embodiment of the present invention, a surface of the supporting structure 11 adjacent to the light-emitting layer 13 is covered with an inorganic layer in order to block impurities in the supporting structure 11 from entering into the light-emitting device of the light-emitting layer 12. At the same time, a layer structure on a surface of the substrate 12 can have the above function as well.

With reference to FIG. 13, which is a flexible display panel according to another embodiment of the present invention. The display panel 20 includes a supporting structure 21, the supporting structure 21 includes multiple supporting bars disposed separately and in parallel. Wherein, the multiple supporting bars 21 are disposed at a back side of the display panel 21. Specifically, for a display panel 20 which is simplified as a substrate, a light-emitting layer and a packaging layer, the multiple supporting bars 21 can be disposed at a side of the substrate away from a viewing side. Specifically, in a top-emission type display panel, the multiple supporting bars 21 can be disposed below the substrate, and in a bottom-emission type display panel 20, the multiple supporting bars 21 can be disposed above the packaging layer. Besides, a length direction of each supporting bars 21 is perpendicular to a bending direction of the display panel 20.

Different from the supporting structures 11 shown in FIG. 1 to FIG. 12, the supporting structure 21 of the present embodiment can be disposed at a display region of the display panel, can also be disposed at a non-display region of the display panel 20. In other words, the supporting structure 21 can be disposed at a middle portion and/or a peripheral edge portion of the display panel 20. Besides, if the supporting structure 11 described above is a micro-structure corresponding to the internal device, the supporting structure 21 in the present embodiment can be understood as a macrostructure. Each supporting structure 21 in a length direction and a width direction can correspond to dozens or hundreds of thin-film transistors.

With combined reference to FIG. 14, the bending direction of the display panel 20 is a direction shown by an arrow in FIG. 14 and horizontally faced toward paper. A length direction of the multiple bars 21 disposed separately and in parallel is a vertical direction.

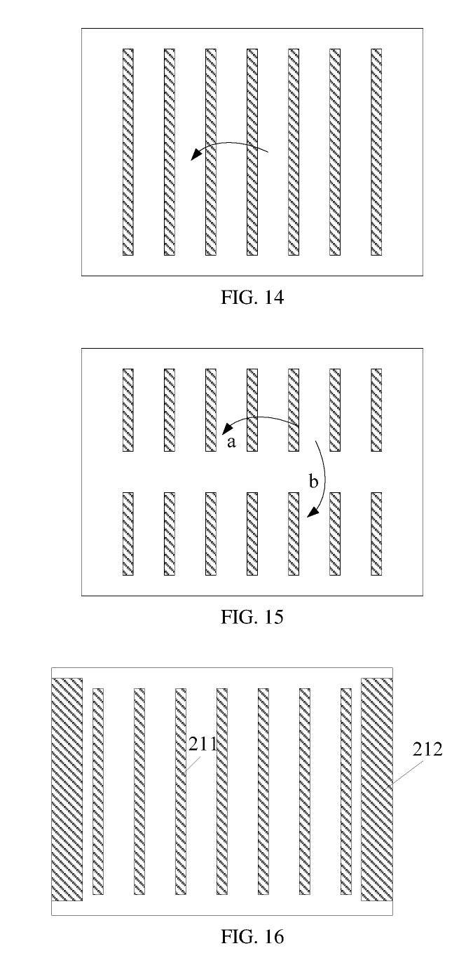

With combined reference to FIG. 15, for the multiple bars 21 disposed separately and in parallel, each supporting bar 21 in the vertical direction includes two disconnected portions. The display panel 20 can be bent horizontally faced toward paper along an arrow “a” shown in the figure, or can be bent vertically faced toward paper along an arrow “b” shown in the figure. That is, the bending direction of the display panel includes a direction horizontally faced toward paper or a direction vertically faced toward paper. It should be noted that in another embodiment of the present invention, each supporting bar 21 can have multiple disconnected structures.

With combined reference to FIG. 16, the supporting structure 21 of the present embodiment includes multiple first supporting bars 211 and two second supporting bars 212. Similarly with the arrangement shown in FIG. 14, a length direction of the multiple supporting bars 211 disposed separately and in parallel is a vertical direction, a bending direction of the display panel 20 is a direction horizontally faced toward paper as shown by an arrow in the figure. The two second supporting bars 212 is disposed at two terminals of the display panel 20 used for maintaining a status of the display panel after bending. Wherein, the two second supporting bars 212 located at two terminals of the display panel 20 are magnetic. Through attraction of magnetism, the status of the display panel 20 after bending is maintained. Of course, other solutions can also be adopted to maintain the status of the display panel 20 after bending. Besides, the first supporting bars 211 disposed at other locations can also be magnetic such that the display panel 20 can be bent as one turn, two turns or multiple turns and maintaining the bending status so as to reduce the space occupied by packaging.

In the present embodiment, preferably, a width of the second supporting bar 212 is greater than a width of the first supporting bar 211 in order to conveniently fix the display panel 20 and to provide a flat display surface for the display panel 20 in order to display a high quality picture without affecting the bending at middle portions at the same time.

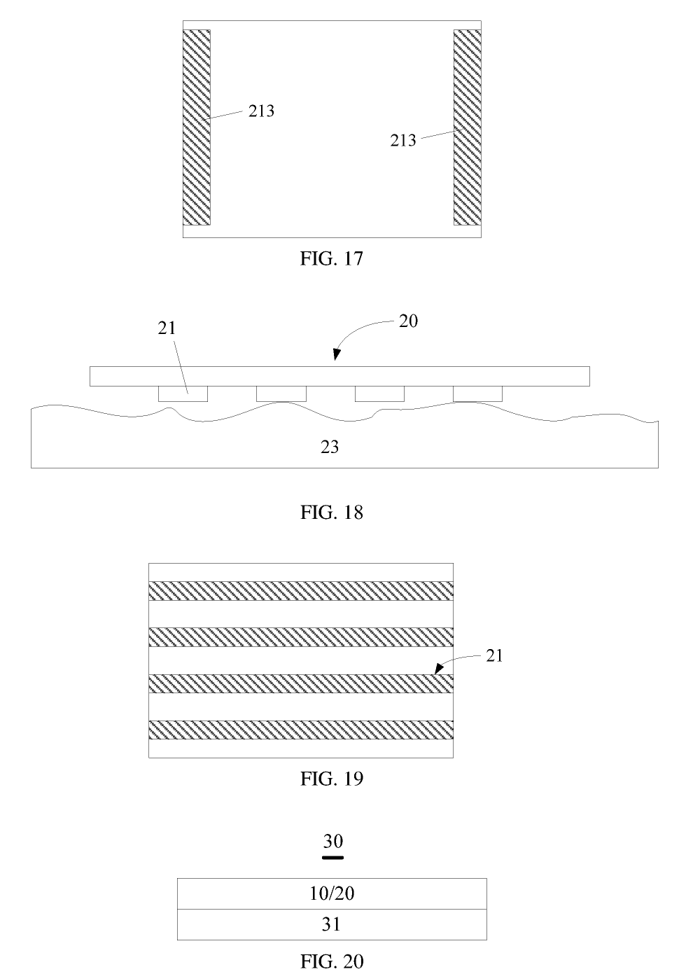

With combined reference to FIG. 17, the supporting structure 21 of the present embodiment can only include two supporting bars 213 disposed at two terminals of the display panel 20. The two supporting bars 213 are the same as the two supporting bars shown in FIG. 16.

Besides, the supporting structure 21 of the embodiment of the present invention can also be disposed at a protection cover or an outer case not directly disposed at a back portion of the substrate of the display panel 20. The protection cover or the outer case is adhered to or wrap the display panel 20 so that the above beneficial effects can also be achieved.

With reference to FIG. 16 and FIG. 17, two supporting bars 212, 213 disposed at two terminal of the display panel 20 can also provide a flat display surface for the display panel 20 when the display panel 20 is placed in a surface of an uneven medium 23. Of course, the supporting bars disposed at other locations of the display panel 20 can also realize the effect. Furthermore, with combined reference to FIG. 18, when the display panel 20 is placed on the uneven surface of the medium 23, the supporting structure 21 of the embodiment of the present invention can provide a flat display surface for the display panel in order to display a high quality picture. At the same time, with combined reference to FIG. 19, the magnetic supporting structure 21 can make the display panel 20 to be easily placed on a wall through attracting by magnetism.

From the embodiments described in FIG. 13 to FIG. 19, the supporting structure 21 can not only provide a bendable direction of the flexible display panel 20, but also can maintain the bending status, and a flat display surface for displaying a high-quality picture when the display panel 20 is placed a surface of an uneven medium. Accordingly, the material of the supporting structure 21 can be ceramics, glass, plastic, metal, etc.

With reference to FIG. 20, which us a flexible display device according to an embodiment of the present invention. The display device 30 includes a flexible display panel such as the display panel 10 described in one embodiment of FIG. 1 to FIG. 12, or, the display panel 20 in one embodiment of FIG. 13 to FIG. 19 so that the previous useful effect can be achieved. Of course, the flexible display panel of the display device 30 can have the supporting structure 11 in one embodiment of FIG. 1 to FIG. 12, or the supporting structure 21 in one embodiment of FIG. 13 to FIG. 19. Therefore, the beneficial effect of the supporting structure 11 and the supporting structure 21 can be achieved.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A flexible display panel, comprising:
a substrate;
a light-emitting layer;
a packaging layer; and
a supporting structure made of a rigid material;
wherein, the light-emitting layer is disposed between the substrate and the packaging layer, and is provided with a thin-film transistor; the supporting structure is disposed at least one location of an upper location, a lower location and an internal location of the substrate and the packaging layer; the supporting structure is formed correspondingly above and/or below the thin-film transistor through etching or adhering by transfer printing; an elastic modulus of the supporting structure is greater than an elastic modulus of the flexible display panel; and a bending strength of the supporting structure is greater than or equal to 400 MPa.

2. The flexible display panel according to claim 1, wherein,
the supporting structure includes multiple stripe-shaped rigid bars, a width of each rigid bar is greater than or equal to a width of a semiconductor layer of the thin-film transistor.

3. A flexible display panel, comprising:
a substrate;
a packaging layer; and
a supporting structure;
wherein, the supporting structure is disposed at least one location of an upper location, a lower location and an internal location of the substrate and the packaging layer.

4. The flexible display panel according to claim 3, wherein, the flexible display panel further includes a light-emitting layer disposed between the substrate and the packaging layer, the light-emitting layer is provided with a thin-film transistor, the supporting structure is formed above and/or below the thin-film transistor, and disposed corresponding to the thin-film transistor.

5. The flexible display panel according to claim 4, wherein, the supporting structure includes multiple stripe-shaped rigid bars, a width of each rigid bar is greater than or equal to a width of a semiconductor layer of the thin-film transistor.

6. The flexible display panel according to claim 4, wherein, the supporting structure includes multiple rigid blocks, an area of each block is less than an area of a sub-pixel of the flexible display panel.

7. The flexible display panel according to claim 4, wherein, an elastic modulus of the supporting structure is greater than an elastic modulus of the flexible display panel; and a bending strength of the supporting structure is greater than or equal to 400 MPa.

8. The flexible display panel according to claim 3, wherein, the flexible display panel includes a display region located at a middle portion and a non-display region located at periphery of the display region, the supporting structure includes a first supporting bar corresponding to the display region and/or a second supporting bar corresponding to the non-display region.

9. The flexible display panel according to claim 8, wherein, a width of the second supporting bar is greater than a width of the first supporting bar.

10. The flexible display panel according to claim 8, wherein, at least one of the first supporting bar and the second supporting bar is magnetic.

11. The flexible display panel according to claim 8, wherein, a length direction of each supporting structure is perpendicular to a bendable direction of the flexible display panel.

12. A flexible display device including a flexible display panel, and the flexible display panel comprises:
a substrate;
a packaging layer; and
a supporting structure;
wherein, the supporting structure is disposed at least one location of an upper location, a lower location and an internal location of the substrate and the packaging layer.

13. The flexible display device according to claim 12, wherein, the flexible display panel further includes a light-emitting layer disposed between the substrate and the packaging layer, the light-emitting layer is provided with a thin-film transistor, the supporting structure is formed above and/or below the thin-film transistor, and disposed corresponding to the thin-film transistor.

14. The flexible display device according to claim 13, wherein, the supporting structure includes multiple stripe-shaped rigid bars, a width of each rigid bar is greater than or equal to a width of a semiconductor layer of the thin-film transistor.

15. The flexible display device according to claim 13, wherein, the supporting structure includes multiple rigid blocks, an area of each block is less than an area of a sub-pixel of the flexible display panel.

16. The flexible display device according to claim 13, wherein, an elastic modulus of the supporting structure is greater than an elastic modulus of the flexible display panel; and a bending strength of the supporting structure is greater than or equal to 400 MPa.

17. The flexible display device according to claim 12, wherein, the flexible display panel includes a display region located at a middle portion and a non-display region located at periphery of the display region, the supporting structure includes a first supporting bar corresponding to the display region and/or a second supporting bar corresponding to the non-display region.

18. The flexible display device according to claim 17, wherein, a width of the second supporting bar is greater than a width of the first supporting bar.

19. The flexible display device according to claim 17, wherein, at least one of the first supporting bar and the second supporting bar is magnetic.

20. The flexible display device according to claim 17, wherein, a length direction of each supporting structure is perpendicular to a bendable direction of the flexible display panel.
